(19) United States
(12) Patent Application Publication
(10) Pub. No.: US 2025/0248053 A1
(43) Pub. Date: Jul. 31, 2025

(54) CHOKE FILTERS IMPLEMENTED USING SUBSTRATE MATERIALS

(71) Applicant: Avago Technologies International Sales Pte. Limited, Singapore (SG)

(72) Inventor: Eric Ingram, Atlanta, GA (US)

(21) Appl. No.: 18/424,150

(22) Filed: Jan. 26, 2024

(51) Int. Cl. H01L 23/50

(52) U.S. Cl. CPC H10D 1/20; H01L 23/50; H10D 1/684

(57) ABSTRACT

Novel tools and techniques are provided for implementing a semiconductor package or a chip package, and more particularly methods, systems, and apparatuses are provided for implementing a semiconductor package or a chip package including a choke. In an embodiment, a semiconductor device can include a choke comprising a first layer comprising a first inductor and a second inductor. A first path of the first inductor can alternates with a second path of the second inductor. The choke can further include a second layer comprising a first capacitor comprising a first plate and a second capacitor comprising a second plate. The first capacitor plate can be coupled in parallel with at least one of the first inductor or the second inductor and the second capacitor can be coupled in parallel with at least one of the first inductor or the second inductor.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for implementing a semiconductor device comprising a choke and capacitive features.

### BACKGROUND

Conductive traces that carry electronic signals have the potential to radiate energy at various frequencies. As serializer/deserializer (SerDes) bus speeds increase over time with future generations of semiconductor devices, the radiation of energy becomes worse as many of the frequencies emitted are not only harmonics of clock and data, but fundamental operating frequencies. Thus, the radiation of energy interferes with other electrical devices or signals in proximity to the radiating source.

Hence, there is a need for more robust and scalable solutions for implementing semiconductor packages and chip packages with chokes. Thus, methods, systems, and apparatuses are provided for implementing semiconductor packages or chip packages with chokes.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a perspective view of an embodiment of a semiconductor device comprising a choke and capacitive features, in accordance with various embodiments;

FIGS. 2A-2D are top perspective views of different layers of the semiconductor device of FIG. 1;

FIGS. 3A and 3B are schematic cross-sectional views of the semiconductor device taken along line A-A of FIG. 1;

FIG. 4 is a graph illustrating the frequencies filtered by the choke of the semiconductor device of FIG. 1;

FIGS. 5A-5C are top views of layers of a choke and capacitive features of another semiconductor device, in accordance with various embodiments;

FIG. 6 is a graph illustrating the frequencies filtered by the choke of the semiconductor device of FIG. 5;

FIGS. 7A and 7B are top views of layers of a first choke and a second choke and capacitive features of the first choke and the second choke, in accordance with various embodiments;

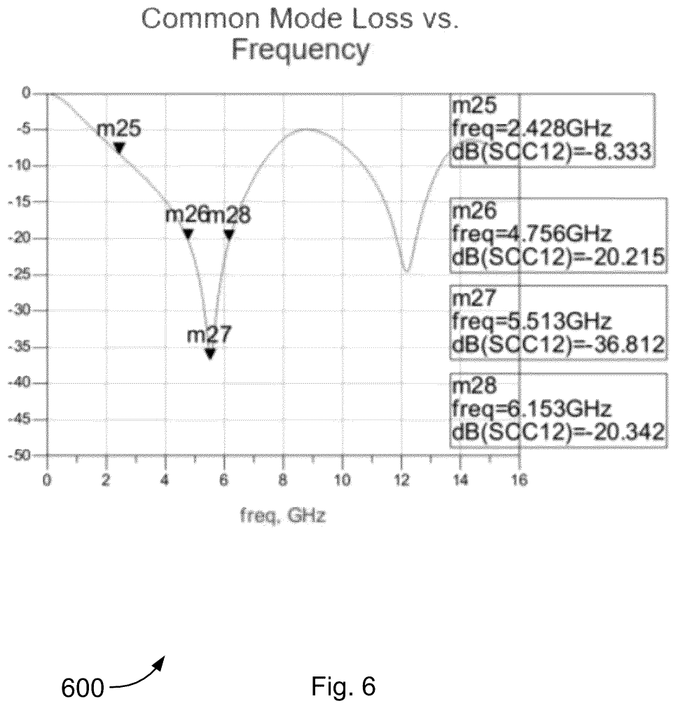

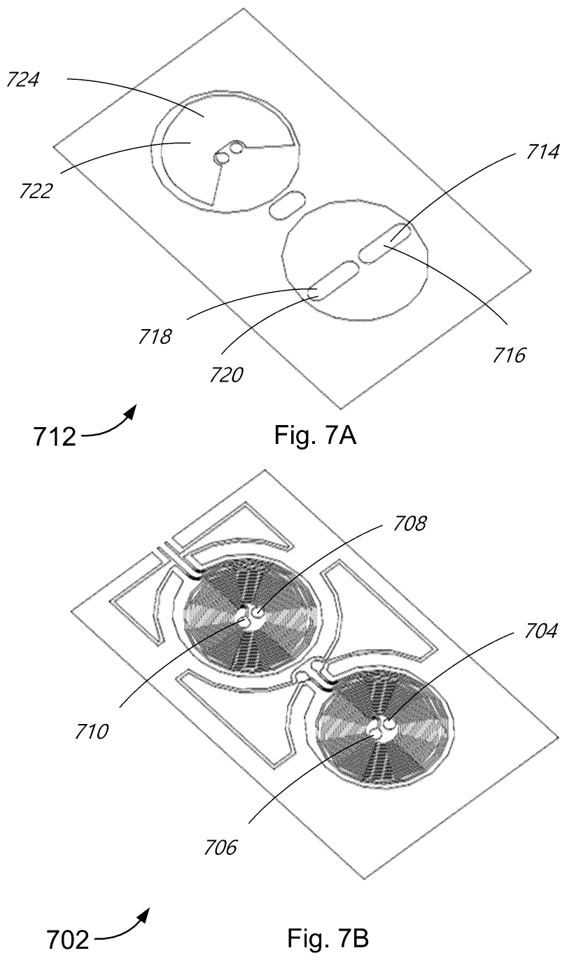

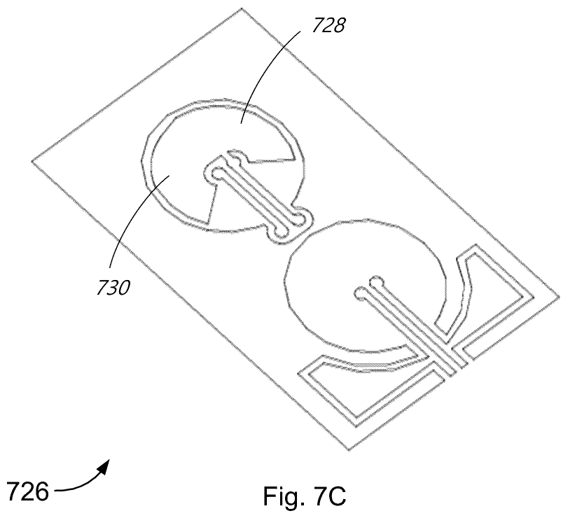

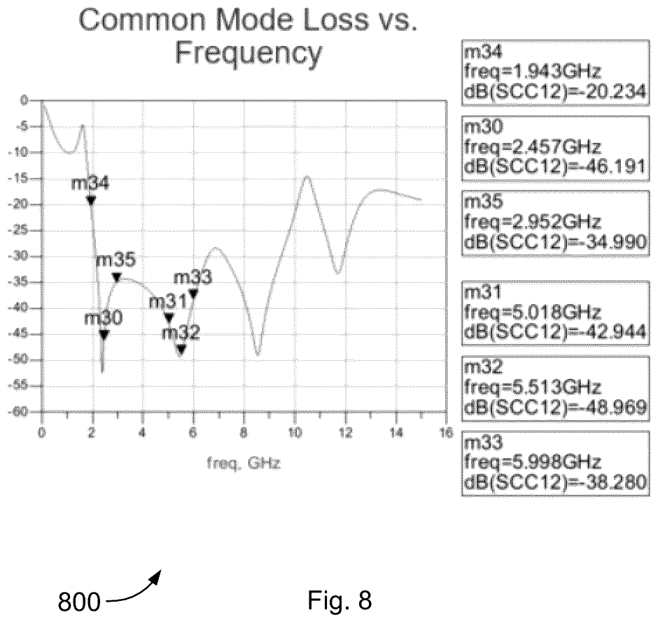

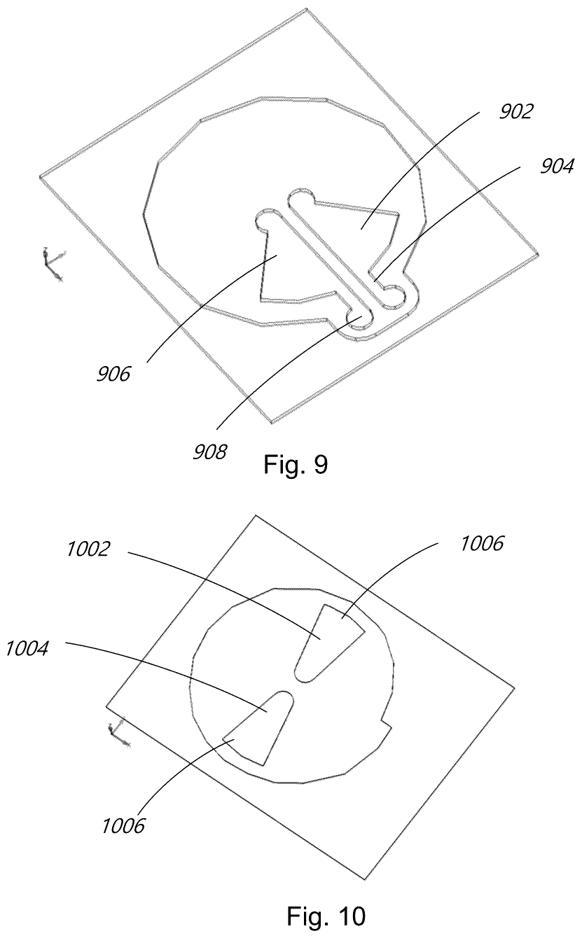

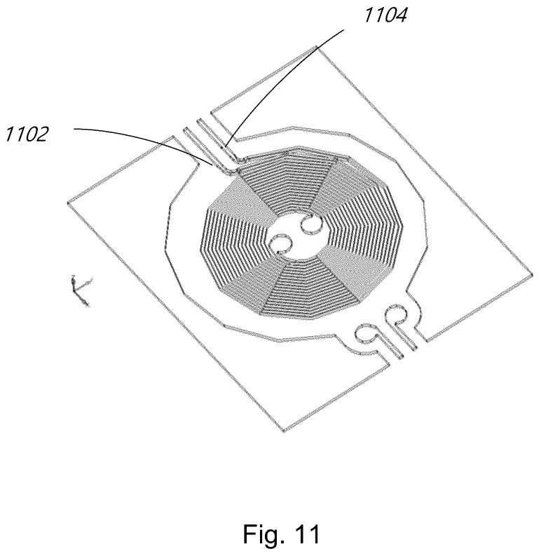

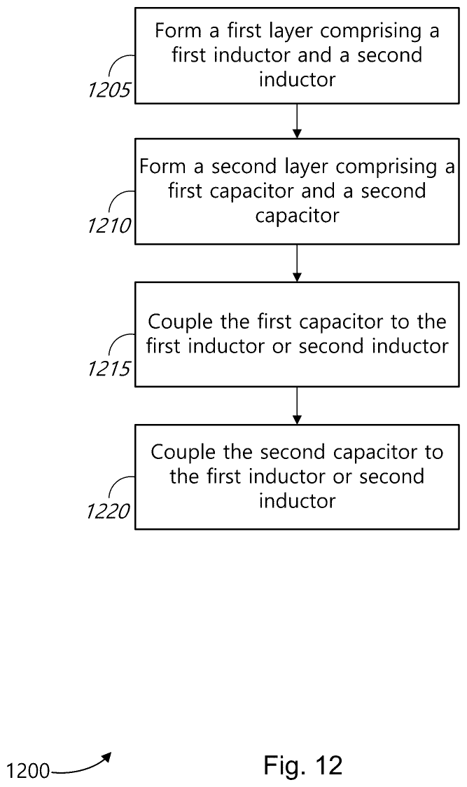

FIG. 6 is a graph illustrating the frequencies filtered by the chokes of FIG. 7;

FIG. 9 is a top view of a capacitive feature of a choke integrated with a signal trace, in accordance with various embodiments;

FIG. 10 is a top view of a capacitive feature of a choke, in accordance with various embodiments;

FIG. 11 is a top view of an inductive feature of a choke, in accordance with various embodiments; and

FIG. 12 is a flow diagram of a method of manufacturing a semiconductor device comprising a choke and capacitive features, in accordance with various embodiments.

### DETAILED DESCRIPTION OF EMBODIMENTS

Various embodiments provide tools and techniques for implementing semiconductor packages or chip packages including one or more chokes and capacitive features are described herein.

In a first aspect, a semiconductor device comprises a choke comprising a first layer comprising a first inductor and a second inductor, wherein a first path of the first inductor alternates with a second path of the second inductor and a second layer comprising a first capacitor comprising a first plate and a second capacitor comprising a second plate. The first plate can be coupled in parallel with at least one of the first inductor or the second inductor and the second plate can be coupled in parallel with at least one of the first inductor or the second inductor.

In some cases, the semiconductor device comprises a printed circuit board, and the printed circuit board comprises the choke. In various instances, the semiconductor device comprises a multi-chip module and the multi-chip module comprises the choke.

In various embodiments, the first capacitor does not include a first parallel plate arranged in parallel to the first plate and the second capacitor does not include a second parallel plate arranged in parallel to the first plate.

In some instances, the first path comprises two or more first coils and the second path comprises two or more second coils, and at least one coil of the two or more first coils alternates with a corresponding coil of the two or more second coils.

In various cases, the first plate couples to a first terminal of the first inductor, and the second plate couples to a second terminal of the second inductor. The first plate can couple to the first path of the first inductor and the second path of the second inductor, and the second plate can couple to the first path of the first inductor and the second path of the second inductor. In some instances, the first plate extends in a first direction along the first path of the first inductor and the second path of the second inductor, and the second plate extends in a second direction opposite the first direction along the first path of the first inductor and the second path of the second inductor. In some embodiments, a first protrusion of the first plate couples to the first path of the first inductor, and a second protrusion of the second plate couples to the second path of the second inductor. In various cases, the first plate is coupled from the first terminal to a third terminal of the first inductor and the second plate is coupled from the second terminal to a fourth terminal of the second inductor.

In some embodiments, the semiconductor device further comprises a third layer comprising a first trace and a second trace, wherein the first trace is coupled to at least one of the first inductor or the first plate and the second trace is coupled to at least one of the second inductor or the second plate. The first trace can be configured to transmit a first High-Definition Multimedia Interface (HDMI) signal, and the second trace can be configured to transmit a second HDMI signal.

In various embodiments, the choke is configured to filter signals at at least one of 2.4 Gigahertz (GHz) or 5 GHz.

In another aspect, a substrate comprises a first layer comprising a first inductor and a second inductor, wherein the first inductor alternates with the second inductor; a second layer comprising a first capacitor comprising a first plate; and at least one of the second layer or a third layer comprising a second capacitor comprising a second plate. The first plate can be coupled to the first inductor and the second plate can be coupled to the second inductor.

In some cases, the substrate can be formed as part of a printed circuit board or a multi-chip module.

In various embodiments, the first plate is coupled from a first terminal to a third terminal of the first inductor and the second plate is coupled from a second terminal to a fourth terminal of the second inductor.

In some instances, the first layer further comprises a third inductor and a fourth inductor. The third inductor can alternate with the fourth inductor and can be spaced apart from the first inductor and the second inductor. The second layer further comprises a third capacitor comprising a third plate and at least of the second layer or the third layer comprises a fourth capacitor comprising a fourth plate. In various cases, the third plate is coupled to the third inductor and the fourth plate is coupled to the fourth inductor. In some instances, the first inductor, the second inductor, the first capacitor, and the second capacitor form a first choke configured to filter a first frequency, and the third inductor, the fourth inductor, the third capacitor, and the fourth capacitor form a second choke configured to filter a second frequency.

In yet another aspect, a method of manufacturing a semiconductor device comprising a choke comprises forming a first layer comprising a first inductor and a second inductor. The first inductor can intertwine with the second inductor. The method can further include forming a second layer comprising a first capacitor comprising a first plate and a second capacitor comprising a second plate; coupling the first plate in parallel with at least one of the first inductor or the second inductor; and coupling the second plate in parallel with at least one of the first inductor or the second inductor.

In various cases, the method further includes forming a dielectric layer between the first layer and the second layer.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

When an element is referred to herein as being “connected,” “coupled,” or “attached” to another element (such as through electrical or communicative connection or coupling), it is to be understood that the elements can be directly connected to the other element, or have intervening elements present between the elements. In contrast, when an element is referred to as being “directly connected,” “directly coupled,” or “directly attached” to another element, it should be understood that no intervening elements are present in the “direct” connection between the elements. However, the existence of a direct connection does not exclude other connections, in which intervening elements may be present.

When an element is referred to herein as being “disposed” or “located” in some manner relative to another element (e.g., disposed on, disposed between, disposed under, disposed adjacent to, or disposed in some other relative manner), it is to be understood that the elements can be directly disposed or located relative to the other element (e.g., disposed directly on another element), or have intervening elements present between the elements. In contrast, when an element is referred to as being “disposed directly” or “located directly” relative to another element, it should be understood that no intervening elements are present in the “direct” example. However, the existence of a direct disposition does not exclude other examples in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components. Additionally, terms such as first, second, third, are merely used to distinguish elements pr components from each other and are not intended to imply an order or sequence unless expressly stated otherwise.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” The term “about” used herein refers to variations from the reference value or ratio of ±10% or less (e.g., ±10%, ±5%, etc.), inclusive of the endpoints of the range.

In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

In existing semiconductor or chip packages, conductive traces that carry electronic signals have the potential to radiate energy at different frequencies. In a non-limiting example, conductive traces carrying high-definition multimedia interface (HDMI) signals have the potential to radiate energy as the HDMI signals are transmitted through the conductive traces. For example, the energy radiated from the conductive traces carrying HDMI signals can interfere with other signals of a semiconductor device such as WiFi signals, Bluetooth signals, cellular signals, or the like. In some cases, chokes can be used to reduce the radiation of the energy from the HDMI signals. However, conventionally, chokes are discrete from the chip, integrated circuit (IC), printed circuit board (PCB), multi-chip module (MCM), substrate, or the like and installed as a separate add-on device after the chip, IC, PCB, MCM, substrate, or the like is manufactured.

The subject technology comprises a semiconductor device (e.g., chip, IC, PCB, MCM, substrate or other semiconductor device or module) that provides an integrated choke formed from one or more materials of the semiconductor device and fabricated as part of the semiconductor device. In various cases, the choke can be formed as one or more conductive layers comprising one or more conductive traces integrated with the semiconductor device. The one or more conductive layers or traces can include copper, aluminum, other conductive material, or other combinations of conductive materials, or the like. The choke can be designed to pass some types of signals (e.g., HDMI signals or the like) but attenuate or impede other types of signals or energy (e.g., 2.4 Gigahertz (GHz) frequencies, 5 GHz frequencies, or the like) from radiating from the traces carrying the signals after the signals have passed through the choke. This functionality allows complex chokes to be implemented on the semiconductor device using only the material used to produce the semiconductor device. In some cases, substantial product cost savings can be realized since the chokes can be printed with or fabricated with the semiconductor device and can take the place of a purchased discrete choke or filter that would otherwise be discrete from the semiconductor device and installed in the semiconductor device after the semiconductor device is fabricated.

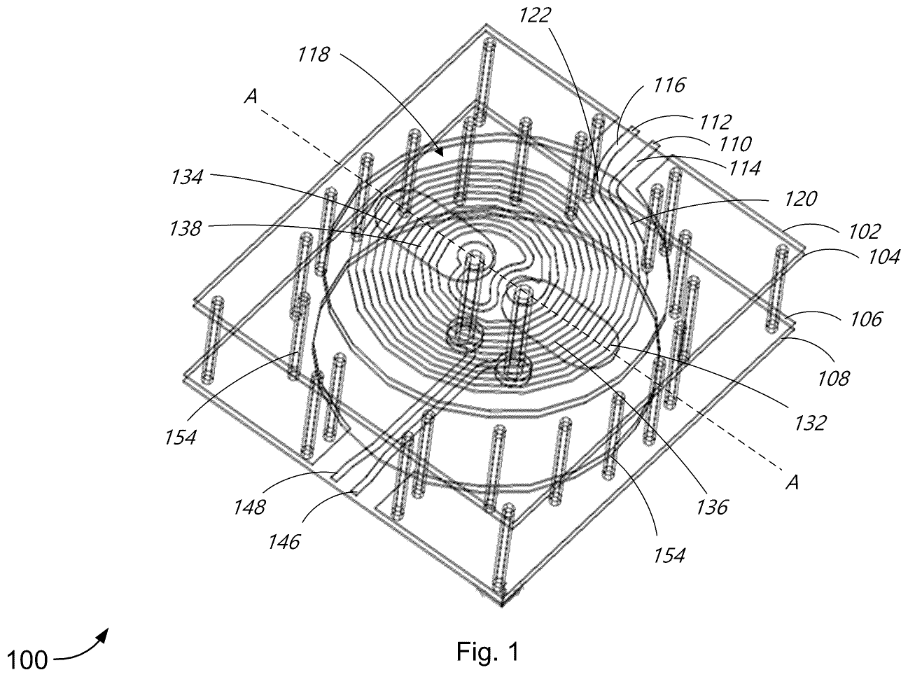

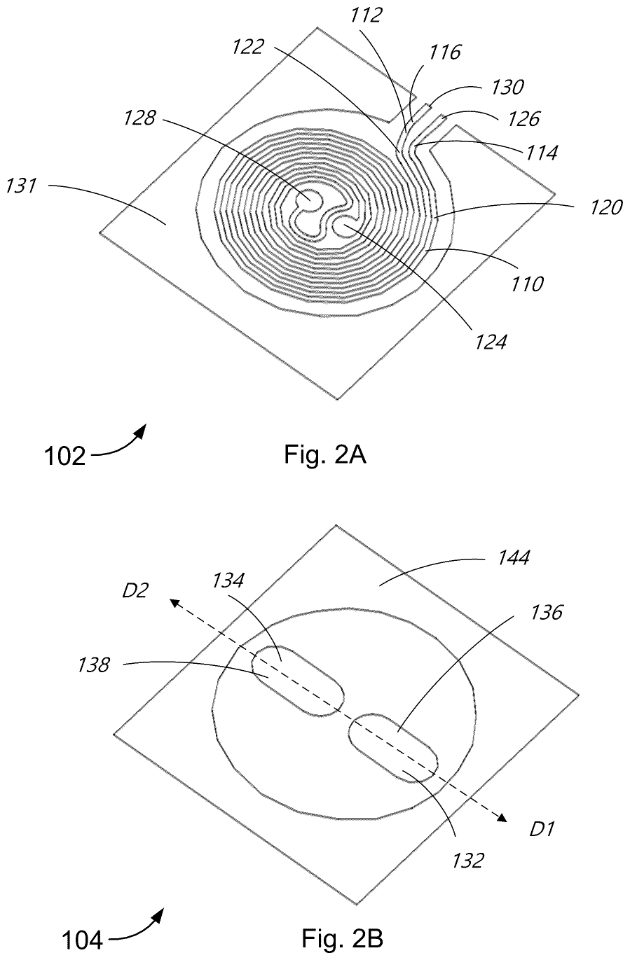

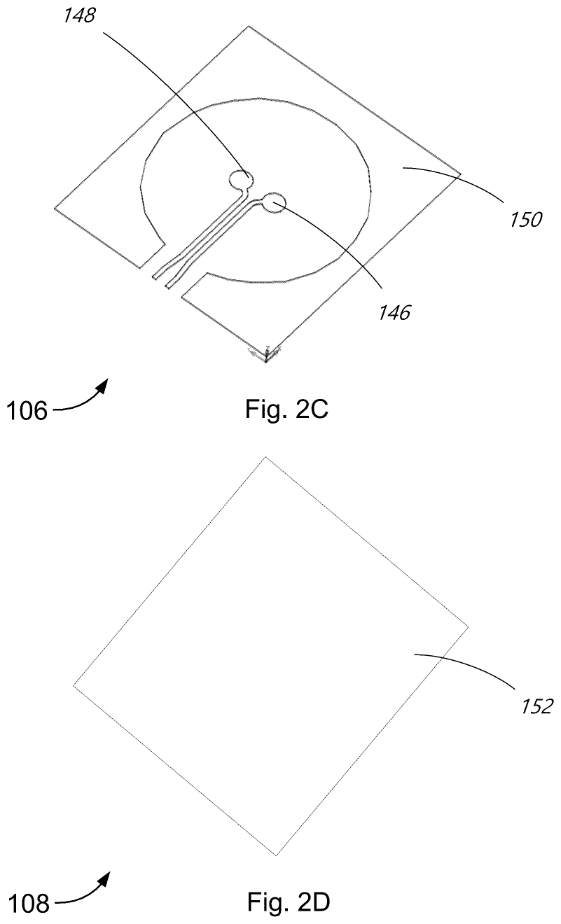

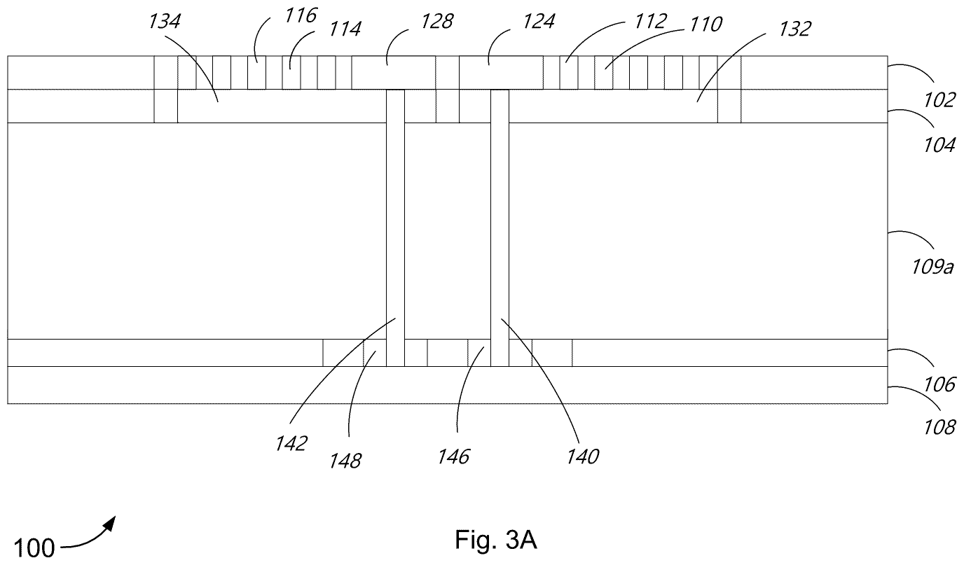

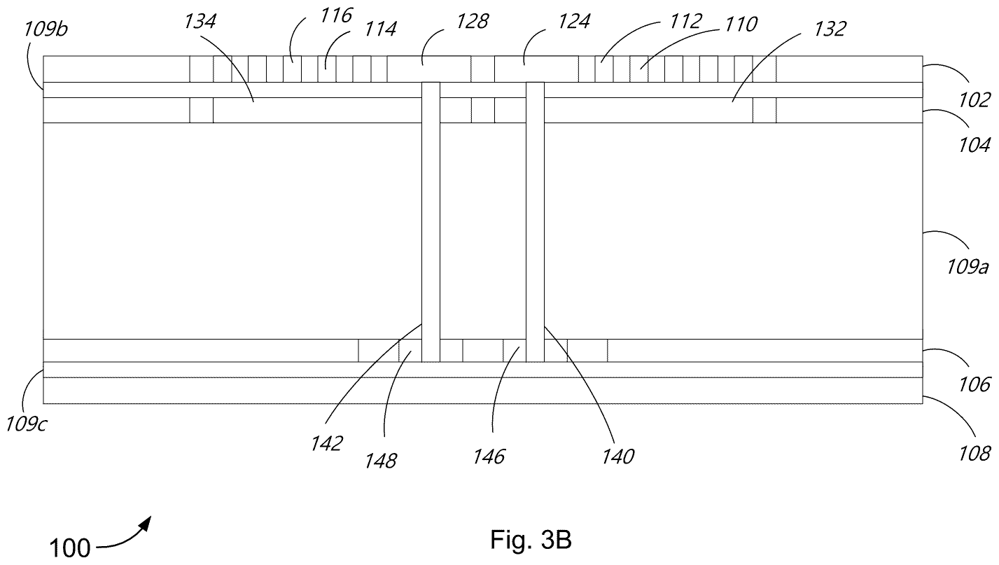

FIG. 1 is a perspective view of an embodiment of a semiconductor device 100 (collectively, semiconductor device 100) comprising transparent layers, in accordance with various embodiments. Although the layers of the semiconductor device 100 are shown as being transparent in FIG. 1, a person of ordinary skill in the art would understand that the layers may not be transparent and that the layers are transparent in FIG. 1 to more easily view the components of semiconductor device 100. FIGS. 2A-2D are top perspective views of different layers of the semiconductor device 100 of FIG. 1. FIGS. 3A and 3B are schematic cross-sectional views of the semiconductor device 100 taken along line A-A of FIG. 1. A person of ordinary skill in the art will understand that semiconductor device 100 can have more or less components or layers than those shown in FIGS. 1-3.

In some cases, semiconductor device 100 can be at least one of a chip, IC, PCB, MCM, substrate or other semiconductor device or module that provides a choke (e.g., choke 118) formed from one or more materials of the semiconductor device 100. In various cases, the semiconductor device 100 could be coupled to a device such as a set-top box, a phone, a gaming console, a laptop, a computer, an access point, a router, a modem, a gateway, or any other device capable of transmitting or receiving signals, or the like. In various cases, the device can be configured to receive or transmit one or more signals such as HDMI signals, WiFi signals, Bluetooth signals, cellular signals, other signals, or the like.

The semiconductor device 100 can include one or more layers. The one or more layers can include, without limitation, one or more dielectric layers, one or more device layers, one or more conducting layers, one or more metal layers, one or more insulating layers, one or more redistribution layers, and/or the like. In some cases, the semiconductor device 100 can comprise a first layer 102 and a second layer 104. In some cases, the semiconductor device 100 can comprise one or more optional layers (e.g., a third layer 106, a fourth layer 108, or the like). The first layer 102, second layer 104, third layer 106, fourth layer 108 or the like can be one or more metal layers comprising one or more conductive traces, grounding planes, or the like. In various cases, one or more optional dielectric layers 109a-c shown in FIGS. 3A and 3B can be formed between each layer or between one or more of the first layer 102, second layer 104, third layer 106, fourth layer 108, or the like.

In various embodiments, the first layer 102 of the semiconductor device 100 comprises a first inductor 110 and a second inductor 112. In some cases, the first inductor 110 and the second inductor 112 can be implemented on the same first layer 102 so that the first inductor 110 and the second inductor 112 are in close proximity to each other. The first inductor 110 and the second inductor 112 can be formed from one or more metallization or conductive traces 114 and 116, respectively (e.g., one or more wires, one or more lines, one or more interconnects, or the like). In various cases, the one or more first conductive traces 114 of the first inductor 110 and the one or more second conductive traces 116 of the second inductor 112 can be constructed from copper, aluminum, or other conductive material, or the like.

In various instances, the conductive traces 114 and 116 can be configured to carry (e.g., transmit, or the like) one or more signals (e.g., differential signals, HDMI signals, or the like). In some cases, the one or more first conductive traces 114 can be configured to carry one or more first signals having a first polarity (e.g., a positive polarity, a negative polarity, or the like) and the one or more second conductive traces 116 can be configured to carry one or more second signals having an opposite polarity of the one or more first signals. In some cases, the one or more first signals and the one or more second signals can have an equal magnitude and an opposite polarity.

In various cases, a choke 118 can comprise at least a portion of the first layer 102 comprising the first inductor and the second inductor. The choke 118 can be used to impede (e.g., attenuate, filter out, block, hinder, obstruct, inhibit, prevent, limit, or the like) one or more first signals, first frequency alternating currents (ACs), or common mode energy from radiating out from the choke 118 while passing one or more second signals, direct current (DC), or one or more second frequency ACs through the conductive traces 114 and 116 in the semiconductor device 100. Common mode energy refers to signal energy that can radiate out from one or more conductive traces and can affect or interfere with other components (e.g., WiFi components, Bluetooth components, cellular components, or the like) in the semiconductor device 100.

In a non-limiting example, if one or more HDMI signals are passing through the conductive traces 114 or 116, energy can radiate out at one or more frequencies from the one or more conductive traces 114 or 116 and interfere with one or more WiFi signals, Bluetooth signals, cellular signals, or the like. Forming the choke 118 can be used to impede energy from the HDMI signals passing through the conductive traces 114 or 116 from radiating out at specific frequencies after the signals have passed through the choke 118 and interfering with one or more WiFi signals, Bluetooth signals, cellular signals, or the like of semiconductor device 100.

The choke 118 can be formed by alternating a first path 120 of the one or more first conductive traces 114 with a second path 122 of the one or more second conductive traces 116. Alternating the first path 120 with the second path 122 can include intertwining or twisting the first path 120 with the second path 122. Intertwining the first path 120 and the second path 122 can include forming the second path 122 between each turn of the first path 120 such that a turn of the first path 120 is not directly next to a next turn of the first path 120. In some cases, as shown in FIGS. 1 and 2A, the conductive traces 114 and 116 of the inductors 110 and 112 can be formed in an alternating circular pattern, one or more alternating coils, a spiral pattern, or the like. Alternatively, the alternating pattern could be triangular, square, rectangular, or the like. Alternating the paths 120 and 122 can reinforce the magnetic flux created by current flowing through the inductors 110 and 112 and therefore increase the inductance of the conductive traces 114 and 116 and thereby impeding energy at certain frequencies from radiating out from the traces after the signals have passed through the choke 118.

In some cases, the first inductor 110 can have a first terminal 124 and a third terminal 126 and the second inductor 112 can have a second terminal 128 and a fourth terminal 130. In some cases, the first terminal 124, third terminal 126, second terminal 128, or fourth terminal 130 can be one or more input terminals or output terminals configured to receive or transmit one or more signals (e.g., HDMI signals, or the like).

In some instances, the first layer 102 can further include a grounding plane 131 surrounding the first inductor 110 and the second inductor 112. The grounding plane 131 can be used to further reduce interference or noise between one or more signals (e.g., HDMI signals, WiFi signals, Bluetooth signals, cellular signals, or the like) of the semiconductor device 100. The grounding plane 131 can also be used as a return path for current from one or more signals from different components on the semiconductor device 100.

In various embodiments, the semiconductor device 100 or choke 118 can further include a first capacitor 132 and a second capacitor 134 on the second layer 104 of the semiconductor device 100. In some cases, the second layer 104 can be above or below the first layer 102. The capacitor 132 can include a first plate 136 and the second capacitor 134 can include a second plate 138. The first plate 136 and the second plate 138 can be coupled (e.g., electrically coupled or the like) to at least one of the first inductor 110 or the second inductor 112. The combination of the inductors 110 and 112 and the capacitors 132 and 134 can form common-mode resonant circuits that impede certain frequencies to a greater extent than chokes without a capacitive coupling. In various cases, at least one of a size or shape of the inductors 110 and 112 and the capacitors 132 and 134, a number of turns of the inductors 110 and 112, an amount of coupling between the inductors 110 and 112 and the capacitors 132 and 134, or the like can be modified or adjusted to impede specific or selected frequencies.

In some instances, the first plate 136 can be a first single capacitor plate 136 and the second plate 138 can be a second single capacitor plate 138. The capacitor 132 including the first single capacitor plate 136 and the second capacitor 134 including the second single capacitor plate 138 are unlike other types of capacitors that have two parallel plates or interdigital “fingers.” The first capacitor 132 and the second capacitor 134 each only have one or a single capacitor plate 136 and 138 without a corresponding second parallel plate. In other words, the first capacitor does not include a first parallel plate arranged in parallel to the first plate and the second capacitor does not include a second parallel plate arranged in parallel to the first plate. By coupling one single capacitor plate 136 from the first terminal 124 toward or to the third terminal 126 of the first inductor 110 and one single capacitor plate 138 from the second terminal 128 toward or to the fourth terminal 130 of the second inductor 112, significantly smaller circuit layouts can be formed. In some cases, the circuit layouts or the semiconductor device 100 can have fewer layers because two parallel capacitor plates do not need to be formed on different layers of the circuit or the semiconductor device 100. These smaller layouts can help avoid unnecessary copper features that introduce parasitic effects that degrade performance of the semiconductor device 100.

Depending on a size and a shape of the first single capacitor plate 136 and the second single capacitor plate 138, each plate can couple to all of the turns of the first inductor 110 or the second inductor 112 or to specific turns or portions of the first inductor 110 or the second inductor 112. In some cases, the first single capacitor plate 136 and the second single capacitor plate 138 can couple to both the first inductor 110 and the second inductor 112. Alternatively, in other cases, the first single capacitor plate 136 can couple to the first inductor 110 and the second single capacitor plate 138 can couple to the second inductor 112. In some cases, the first single capacitor plate 136 can couple to the first inductor 110 without coupling to the second inductor 112 and the second single capacitor plate 138 can couple to the second inductor 112 without coupling to the first inductor 110. In order to ensure that the first single capacitor plate 136 does not couple to the second inductor 112, the first single capacitor plate 136 can be etched in locations where the second inductor could contact the first single capacitor plate 136. A similar process could be performed for the second single capacitor plate 138. In some cases, the first single capacitor plate 136 can couple to the first terminal 124 of the first inductor 110 via a first via 140 and the second single capacitor plate 138 can couple to the second terminal 128 of the second inductor 112 via a second via 142.

In various cases, the first single capacitor plate 136 or the second single capacitor plate 138 can be electrically in parallel with at least one of the first inductor 110 or the second inductor 112. In some cases, the first single capacitor plate 136 extends in a first direction D1 and couples to both of the first path 120 of the first inductor 110 and the second path 122 of the second inductor 112 and the second single capacitor plate 138 extends in a second direction D2 opposite the first direction D1 and couples to both of the first path 120 of the first inductor 110 and the second path 122 of the second inductor 112. Alternatively, in other cases, the first single capacitor plate 136 extends in the first direction D1 and couples to the first path 120 of the first inductor 110 and the second single capacitor plate 138 extends in the second direction D2 opposite the first direction D1 and couples to the second path 122 of the second inductor 112.

In some instances, the second layer 104 can further include a grounding plane 144 surrounding the first capacitor 132 and the second capacitor 134. The grounding plane 144 can operate in a similar manner as grounding plane 131.

In some embodiments, the semiconductor device 100 can further include a first signal trace 146 and a second signal trace 148. The first signal trace 146 and the second signal trace 148 can be implemented or formed on a third layer 106 of the semiconductor device 100. The third layer 106 can be formed above or below layers 102 and 104. Alternatively, in other cases, the first signal trace 146 and the second signal trace 148 can be implemented on the first layer 102 or the second layer 104. In some cases, the first signal trace 146 can be coupled to the first inductor 110 or the first capacitor 132 via the first via 140 and the second signal trace 148 can be coupled to the second inductor 112 or the second capacitor 134 via the second via 142. In various cases, the first signal trace 146 can be configured to transmit or receive one or more signals (e.g., HDMI signals or the like) to or from the one or more first conductive traces 114 and the second signal trace 148 can be configured to transmit or receive one or more signals (e.g., HDMI signals or the like) to or from the one or more second conductive traces 116. In some cases, the third layer 106 can further include a grounding plane 150 surrounding the first signal trace 146 and the second signal trace 148. The grounding plane 150 can operate in a similar manner as grounding plane 131.

In some cases, the semiconductor device 100 can further include one or more optional grounding planes 152 above or below the first signal trace 146 and the second signal trace 148. For example, the grounding plane 152 can be included on fourth layer 108 below third layer 106 as shown in FIGS. 1 and 3. The grounding plane 152 can operate in a similar manner as grounding plane 131.

In various instances, the semiconductor device 100 can further include one or more vias 154 coupling one or more of the grounding planes 131, 144, 150, 152 or the like. The one or more vias 154 can be configured to reduce interference or noise between one or more signals (e.g., HDMI signals, WiFi signals, Bluetooth signals, cellular signals, or the like) of the semiconductor device 100. The one or more vias 154 can also be used as a return path for current from one or more signals from different components on the semiconductor device 100.

In various cases, as discussed above and below, the first inductor 110, second inductor 112, first capacitor 132, and second capacitor 134 can be adjusted or modified to filter out or impede specific frequencies from radiating out from the traces after the signals have passed through the choke 118. Different embodiments of the choke 118 impeding different frequencies are shown below with respect to FIGS. 1-8.

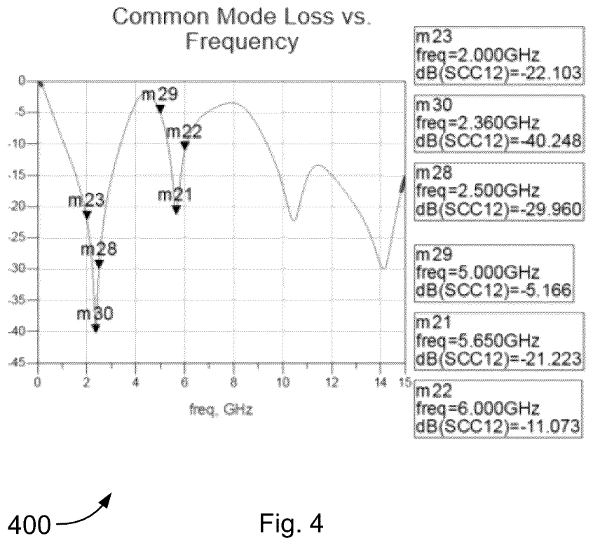

In the embodiment shown in FIGS. 1-3, the choke 118 can be configured to filter out 2.4 GHz and some other frequencies as shown in Graph 400 of FIG. 4. In order to filter 2.4 GHz, the first single capacitor plate 136 is coupled (e.g., electrically coupled, or the like) to the first terminal 124 of the first inductor via a first via 140 and is electrically in parallel to both of the first inductor 110 and the second inductor 112 and the second single capacitor plate 138 is coupled to the second terminal 128 of the second inductor 112 via the second via 142 and is electrically in parallel to both of the first inductor 110 and the second inductor 112. In other words, the first single capacitor plate 136 is coupled to the first terminal 124 of the first inductor 110 via the first via 140 and is coupled to one or more conductive traces 114 and 116 of both of the first inductor 110 and the second inductor 112 and the second single capacitor plate 138 is coupled to the second terminal 128 of the second inductor 112 via the second via 142 and is coupled to one or more conductive traces 114 and 116 of both of the first inductor 110 and the second inductor 112. FIG. 4 shows the performance of the choke of FIGS. 1-3 to filter out 2.4 GHz. As shown in Graph 400 of FIG. 4, 2.4 GHz has the greatest rejection of all the frequencies and is impeded from radiating out from the traces after the signals have passed through the choke 118.

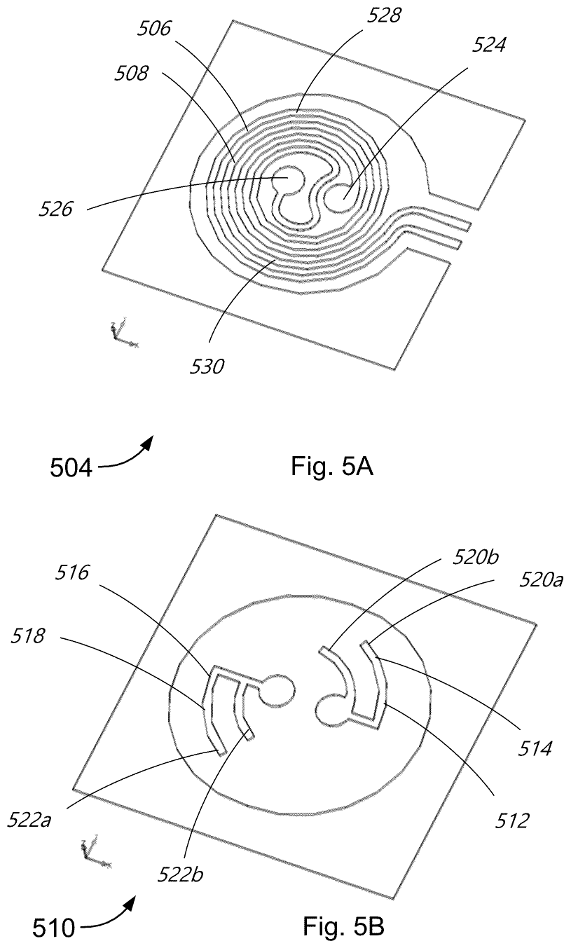

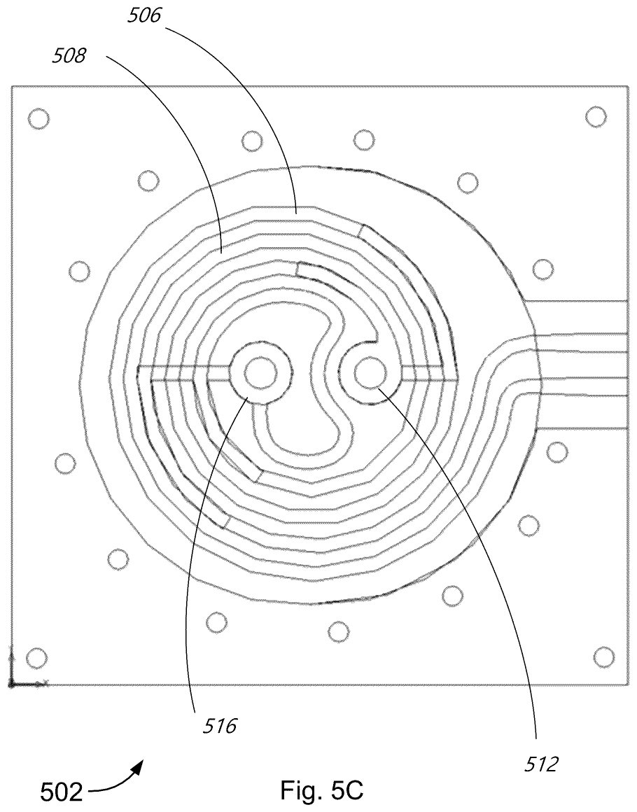

In the embodiment shown in FIGS. 5A-5C, the choke 502, shown in FIG. 5C, can be configured to filter out 5 GHz. The choke 502 of FIG. 5 can be implemented in semiconductor device 100 or another semiconductor device instead of or in addition to choke 118 of FIGS. 1-3. The choke 502 can comprise a first layer 504 having a first inductor 506 and a second inductor 508. The inductors 506 and 508 can be similar to the inductors 110 and 112 described with respect to FIGS. 1-3. The choke 502 can further include a second layer 510 comprising a first capacitor 512 comprising a first single capacitor plate 514 and a second capacitor 516 comprising a second single capacitor plate 518.

In some cases, the first single capacitor plate 514 can include one or more first protrusions or fingers 520a and 520b (collectively, first protrusions 520) and the second single capacitor plate 518 can include one or more second protrusions or fingers 522a and 522b (collectively, second protrusions 522). The one or more first protrusions 520 can be configured to couple to one or more turns or portions of the first inductor 506 without coupling to one or more turns of the second inductor 508 while the one or more second protrusions 522 can be configured to couple to one or more turns or portions of the second inductor 508 without coupling to one or more turns of the first inductor 508. The coupling of the first single capacitor plate 514 to the first inductor 506 and the coupling of the second single capacitor plate 518 to the second inductor 508 is shown in choke 502 of FIG. 5C. In various cases, the one or more first protrusions 520 can be sized and shaped to follow a path of the first inductor 506 while the one or more second protrusions 522 can be sized and shaped to follow a path of the second inductor 508.

In order to filter 5 GHZ, the first single capacitor plate 514 can be coupled (e.g., electrically coupled, or the like) to a first terminal 524 of the first inductor 506 and can be electrically in parallel to the first inductor 506. In other words, the first single capacitor plate 514 is coupled to the first terminal 524 of the first inductor 506 and one or more first protrusions 520 of the first single capacitor plate 514 are coupled to one or more turns or portions of the one or more conductive traces 528 of the first inductor 506. The second single capacitor plate 518 can coupled to a second terminal 526 of the second inductor 508 and can be electrically in parallel to the second inductor 508. In other words, the second single capacitor plate 518 is coupled to the second terminal 526 of the second inductor 508 and one or more first protrusions 520 of the second single capacitor plate 518 are coupled to one or more turns or portions of the one or more conductive traces 530 of the second inductor 508. As shown in Graph 600 of FIG. 6, although 5.5 GHz has the greatest rejection of all the frequencies, 5 GHz is also impeded from radiating out from the traces after the signals have passed through the choke 502.

In some cases, multiple chokes can be implemented in semiconductor device 100 instead of or in addition to choke 118 of FIGS. 1-3 as shown in FIG. 7. Each choke can be configured to filter a different frequency (e.g., 2.4 GHz, 5 GHZ, or the like). In FIG. 7, two chokes can be formed using four inductors and four capacitors. The first choke can comprise a first layer 702, shown in FIG. 7B, having a first inductor 704 and a second inductor 706. The second choke can comprise the first layer 702 and include a third inductor 708 and a fourth inductor 710. The third inductor 708 and the fourth inductor 710 can be spaced apart from the first inductor 704 and the second inductor 706. The inductors 704-710 can be similar to the inductors 110 and 112 described with respect to FIGS. 1-3.

The first choke can further include a second layer 712, shown in FIG. 7A, comprising a first capacitor 714 comprising a first single capacitor plate 716 and a second capacitor 718 comprising a second single capacitor plate 720. The second choke can further include the second layer 712 and include a third capacitor 722 comprising a third single capacitor plate 724. The second choke can further include a third layer 726, shown in FIG. 7C, comprising a fourth capacitor 728 and a fourth single capacitor plate 730. In various cases, the first layer 702 can be coupled between the second layer 712 and the third layer 726. In some instances, the first, second, third, and fourth capacitor can all be implemented on the second layer 712 or different variations or configurations of the first, second, third, and fourth capacitor can be implemented on the second layer 712 and the third layer 726. In a non-limiting example, the first and third capacitor could be implemented on the second layer 712 while the second and fourth capacitor could be implemented on the third layer 726.

The first choke of FIG. 7 can be configured to filter 5 GHz. In order to filter 5 GHz, the first single capacitor plate 716 can be coupled (e.g., electrically coupled, or the like) to the first inductor 704 and electrically in parallel with the first inductor 704. In some cases, the first single capacitor plate 716 can be coupled to one or more turns or portions of the one or more turns of the first inductor 704 in a similar manner as described above with respect to FIG. 5. In some cases, the first single capacitor plate 716 can be selectively etched to ensure that only selected portions of the first single capacitor plate 716 couple to the first inductor 704 or the second inductor 706. The second single capacitor plate 720 can be coupled to the second inductor 706 and can be electrically in parallel to the second inductor 706. In some cases, the second single capacitor plate 720 can be coupled to one or more turns or portions of the one or more turns of the second inductor 706 in a similar manner as described above with respect to FIG. 5. In some cases, the second single capacitor plate 720 can be selectively etched to ensure that only selected portions of the second single capacitor plate 720 couple to the first inductor 704 or the second inductor 706.

The second choke can be configured to filter 2.4 GHz. In order to filter 2.4 GHz, the third single capacitor plate 724 can be coupled to the third inductor 708 and is electrically in parallel to at least one of the third inductor 708 or the fourth inductor 710. In some cases, the third single capacitor plate 724 can be coupled to one or more turns or portions of the one or more turns of the third inductor 708 in a similar manner as described above with respect to FIG. 5. In some cases, the third single capacitor plate 724 can be selectively etched to ensure that only selected portions of the third single capacitor plate 724 couple to the third inductor 708 or the fourth inductor 710. The fourth single capacitor plate 730 can be coupled to the fourth inductor 710 and can be electrically in parallel to at least one of the third inductor 708 or the fourth inductor 710. In some cases, the fourth single capacitor plate 730 can be coupled to one or more turns or portions of the one or more turns of the fourth inductor 710 in a similar manner as described above with respect to FIG. 5. In some cases, the fourth single capacitor plate 730 can be selectively etched to ensure that only selected portions of the fourth single capacitor plate 730 couple to the third inductor 708 or the fourth inductor 710.

Graph 800 of FIG. 8 shows that both 2.4 GHz and 5 GHz are impeded from radiating out from the traces after the signals have passed through the chokes of FIG. 7.

In some embodiments, as shown in FIG. 9, a first single capacitor plate 902 can be integrated with and extend from a first signal trace 904 and the second single capacitor plate 906 can be integrated with and extend from a second signal trace 908. The first single capacitor plate and the second single capacitor plate can operate in a similar manner as the capacitor plates described in FIGS. 1-8 while the first signal trace and the second signal trace can operate in a similar manner as the signal traces described in FIGS. 1-3. The first signal trace 904 and the second signal trace 908 can be used to transmit or receive one or more signals from the conductive traces of the one or more inductors described above with respect to FIGS. 1-8. The first single capacitor plate 902 or the second single capacitor plate 906 can be configured to contact at least one of the first inductor or the second inductor in different ways as described in FIGS. 1-8 to filter out different frequencies.

In some cases, as shown in FIG. 10, a first single capacitor plate 1002 and a second single capacitor plate 1004 can be tapered to couple energy to one or more selected portions of the one or more inductors. In FIG. 10, the first single capacitor plate 1002 and the second single capacitor plate 1004 are wider near an outer portion 1006 of the capacitor plates. Therefore, more energy can be coupled to the outer most portion of the one or more inductors.

In various instances, as shown in FIG. 11, a first inductor 1102 and a second inductor 1104 can be more symmetrical and uniform than the inductors shown in FIGS. 1-3. In the embodiment shown in FIG. 11, the path of the first inductor 1102 aligns with the path of the second inductor 1104 and alternates with the path of the second inductor 1104.

FIG. 12 is a flow diagram of a method of manufacturing a semiconductor device, in accordance with various embodiments. The method described in FIG. 12 is one way the components of FIGS. 1-11 can be manufactured. However, other methods may be used to manufacture the components of FIGS. 1-11.

The method 1200 may begin, at block 1205 by forming a first layer comprising a first inductor and a second inductor. The first inductor can alternate with the second inductor in a similar manner as the manner described in FIGS. 1-3. Next, the method 1200 can include, at block 1210, forming a second layer comprising a first capacitor comprising a first single capacitor plate and a second capacitor comprising a second single capacitor plate. In some cases, one or more dielectric layers can be formed between the two or more layers of the semiconductor device formed by method 1200. In various cases, a choke (e.g., choke 118 or the like) can be formed by forming the first layer comprising the first inductor and the second inductor and forming the second layer comprising the first capacitor and the second capacitor.

In various cases, the choke, the first layer, the second layer, or the dielectric layer can be formed as one or more layers of a semiconductor device (e.g., a chip, IC, PCB, MCM, substrate or other semiconductor device or module). In other words, the choke, the first layer, the second layer, or the dielectric layer can be manufactured or fabricated with the semiconductor device and be contained or integrated within the semiconductor device. In a non-limiting example, the choke, the first layer, the second layer, or the dielectric layer can be formed as one or more layers of a PCB and integrated into the structure of the PCB. In this way, the choke is integrated into the structure of the PCB and is not a separate discrete device that can be coupled to the PCB after the PCB is manufactured.

The method 1200 can then continue to optional block 1215 and couple the first single capacitor plate in parallel with at least one of the first inductor or the second inductor. The, the method at optional block 1220 can include coupling the second capacitor in parallel with at least one of the first inductor or the second inductor. Coupling the first single capacitor plate or the second single capacitor plate to at least one of the first inductor or the second inductor can be similar to the processes described with respect to FIGS. 1-11. In some cases, in order to couple the first single capacitor plate or the second single capacitor plate to at least one of the first inductor or the second inductor, the first single capacitor plate or the second single capacitor plate can be etched to ensure selected portions of the first single capacitor plate or the second single capacitor plate couple to at least one of the first inductor or the second inductor. In some cases, the first single capacitor plate or the second single capacitor plate can be etched to ensure that selected portions of the first single capacitor plate or the second single capacitor plate do not couple or contact selected portions of the first inductor or the second inductor.

The techniques and processes described above with respect to various embodiments may be used to manufacture the semiconductor devices or components of FIGS. 1-11, and/or components thereof, as described herein.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. A semiconductor device comprising:
a choke comprising:
a first layer comprising a first inductor and a second inductor, wherein a first path of the first inductor alternates with a second path of the second 4 inductor; and
a second layer comprising a first capacitor comprising a first plate and a second capacitor comprising a second plate, wherein the first plate is coupled in parallel with at least one of the first inductor or the second inductor and the second plate is coupled in parallel with at least one of the 9 first inductor or the second inductor.

2. The semiconductor device of claim 1, wherein the semiconductor device comprises a printed circuit board, and wherein the printed circuit board comprises the choke.

3. The semiconductor device of claim 1, wherein the semiconductor device comprises a multi-chip module, and wherein the multi-chip module comprises the choke.

4. The semiconductor device of claim 1, wherein the first capacitor does not include a first parallel plate arranged in parallel to the first plate and wherein the second capacitor does not include a second parallel plate arranged in parallel to the first plate.

5. The semiconductor device of claim 1, wherein the first path comprises two or more first coils and the second path comprises two or more second coils, and wherein at least one coil of the two or more first coils alternates with a corresponding coil of the two or more second coils.

6. The semiconductor device of claim 1, wherein the first plate couples to a first terminal of the first inductor, and wherein the second plate couples to a second terminal of the second inductor.

7. The semiconductor device of claim 6, wherein the first plate couples to the first path of the first inductor and the second path of the second inductor, and wherein the second plate couples to the first path of the first inductor and the second path of the second inductor.

8. The semiconductor device of claim 7, wherein the first plate extends in a first direction along the first path of the first inductor and the second path of the second inductor, and wherein the second plate extends in a second direction opposite the first direction along the first path of the first inductor and the second path of the second inductor.

9. The semiconductor device of claim 6, wherein a first protrusion of the first plate couples to the first path of the first inductor, and wherein a second protrusion of the second plate couples to the second path of the second inductor.

10. The semiconductor device of claim 6, wherein the first plate is coupled from the first terminal to a third terminal of the first inductor and the second plate is coupled from the second terminal to a fourth terminal of the second inductor.

11. The semiconductor device of claim 1, the semiconductor device further comprising:
a third layer comprising a first trace and a second trace, wherein the first trace is coupled to at least one of the first inductor or the first plate and the second trace is coupled to at least one of the second inductor or the second plate.

12. The semiconductor device of claim 11, wherein the first trace is configured to transmit a first High-Definition Multimedia Interface (HDMI) signal, and wherein the second trace is configured to transmit a second HDMI signal.

13. The semiconductor device of claim 1, wherein the choke is configured to filter signals at at least one of 2.4 Gigahertz (GHz) or 5 GHz.

14. A substrate comprising:
a first layer comprising a first inductor and a second inductor, wherein the first inductor alternates with the second inductor;
a second layer comprising a first capacitor comprising a first plate; and
at least one of the second layer or a third layer comprising a second capacitor comprising a second plate, wherein the first plate is coupled to the first 6 inductor and the second plate is coupled to the second inductor.

15. The substrate of claim 14, wherein the substrate is formed as part of a printed circuit board or a multi-chip module.

16. The substrate of claim 14, wherein the first plate is coupled from a first terminal to a third terminal of the first inductor and the second plate is coupled from a second terminal to a fourth terminal of the second inductor.

17. The substrate of claim 14, wherein
the first layer further comprises a third inductor and a fourth inductor, wherein the third inductor alternates with the fourth inductor and is spaced apart from the first inductor and the second inductor,
the second layer further comprises a third capacitor comprising a third plate; and
at least of the second layer or the third layer comprises a fourth capacitor comprising a fourth plate, and
wherein the third plate is coupled to the third inductor and the fourth plate is coupled to the fourth inductor.

18. The substrate of claim 17, wherein the first inductor, the second inductor, the first capacitor, and the second capacitor form a first choke configured to filter a first frequency, and wherein the third inductor, the fourth inductor, the third capacitor, and the fourth capacitor form a second choke configured to filter a second frequency.

19. A method of manufacturing a semiconductor device comprising a choke, the method comprising:
forming a first layer comprising a first inductor and a second inductor, wherein the first inductor intertwines with the second inductor;
forming a second layer comprising a first capacitor comprising a first plate and a second capacitor comprising a second plate;
coupling the first plate in parallel with at least one of the first inductor or the second inductor; and
coupling the second plate in parallel with at least one of the first inductor or the second inductor.

20. The method of claim 19, further comprising:
forming a dielectric layer between the first layer and the second layer.
